(19) United States
(12) Patent Application Publication
(10) Pub. No.: US 2011/0069435 A1
(43) Pub. Date: Mar. 24, 2011

(54) DISPLAY DEVICE HOLDING STRUCTURE

(76) Inventor: Shinji Serizawa, Tokyo (JP)

(21) Appl. No.: 12/993,416

(22) PCT Filed: Apr. 30, 2009
(86) PCT No.: PCT/JP2009/001963

§ 371 Date: Nov. 18, 2010

(30) Foreign Application Priority Data
Jun. 10, 2008 (JP) 2008-151879

(51) Int. Cl. H05K 7/00

(52) U.S. Cl. 361/679.01

(57) ABSTRACT

A display device holding structure includes a holding member (30) for housing and holding a display unit (400); a lid member (20) that is superposed on the holding member (30) to be united to thus forma display device (6); a support means (100, 800, 900) that is provided between the one-end side and a main body (500) of the display device (6), and supports the display device (6) openably and closably, and reversibly with respect to the display device main body (500); a lock concavity (25) provided on the other-end side of the display device (6), for locking the other-end side to the main body (500); and a lock member (150) provided in the main body (500) to be engageable/disengageable with the lock concavity (25). The display device holding structure is further arranged such that the lock concavity (25) is provided in either of the holding member (30) and the lid member (20).

### TECHNICAL FIELD

The present invention relates to a display device holding structure for allowing a display panel such as a display disposed on the ceiling of an automobile to be adjusted to a position where a viewer can comfortably see, and then allowing the display panel to be locked and held at a housed state that is closed to a position along the ceiling.

### BACKGROUND ART

For a conventional display device holding structure, it is configured to have an initial-position releasing means for releasing the state of an initial position state where one surface of an inner body is exposed with the inner body disposed inside an outer body to urge the inner body in a direction away from the outer body (see, e.g., Patent Document 1).

### PRIOR ART DOCUMENTS

### Patent Documents

Patent Document 1: JP-A-2007-303843

The conventional display device holding structure is arranged as discussed above, and the technique disclosed by Patent Document 1 makes no reference to the improvement of quake-proof performance of a display device. For this reason, there is a problem such that variations between components thereof can be large, thus causing the operating force in the transition from one holding position to another and the quake-proof performance to vary greatly between the structures.

The present invention has been accomplished to solve the above-mentioned problem, and an object of the present invention is to provide a display device holding structure of which the quake-proof performance is enhanced, and which can hold a display device in a stable condition.

### SUMMARY OF THE INVENTION

The present invention is provided a display device holding structure arranged in a display device main body that includes: a holding member for housing and holding a display unit; a lid member that is superposed on the holding member to be united to thus form a display device; a support means provided between one-end side of the display device and the main body such that the display device can be closed, opened, and reversed relative to the main body; a lock concavity, provided on the other-end side of the display device, for locking the other-end side to the main body; and a lock member provided in the main body to be engageable/disengageable with the lock concavity, wherein the lock concavity is provided in either of the holding member and the lid member.

According to the present invention, the lock concavity is provided in either of the holding member and the lid member which is superposed on the holding member and unites with the member. Thus, there can be provided a display device holding structure in which variations between components can be restricted, of which the quake-proof performance is enhanced, and which can hold a display device in a stable condition.

### BRIEF DESCRIPTION OF THE DRAWINGS

FIG. 1 is an exploded perspective view of a lid member and a holding member constituting a display device.

FIG. 2 is a sectional view of a display device main body.

FIG. 3 is a partially enlarged view of the display device main body.

FIG. 4 is a partially enlarged view of the display device main body.

FIG. 5 is an exploded perspective view showing a display unit and a holder in a disassembled state.

FIG. 6 is a perspective view of the holding member.

FIG. 7 is a partially enlarged view of the display device main body.

FIG. 8 is a partially enlarged view of the display device main body.

FIG. 9 is a front view explaining an example where display devices are provided in an automobile interior.

FIG. 10 is a front view explaining an example where display devices are provided in an automobile interior.

FIG. 11 is a front view explaining an example where display devices are provided in an automobile interior.

FIG. 12 is a perspective view showing a state where the display device is housed in the display device main body.

FIG. 13 is a perspective view showing a state where the display device is opened downwardly from the display device main body.

FIG. 14 is a perspective view showing a state where the display device is on the way to be reversed with the display device opened downwardly from the display device main body.

FIG. 15 is a perspective view showing a state where the display device is reversed from the state shown in FIG. 13 with the display device opened downwardly from the display device main body.

FIG. 16 is a perspective view showing a state where the display device is housed in the display device main body with the display device reversed with respect to the state shown in FIG. 12.

FIG. 17 is a sectional view of a display device main body.

FIG. 18 is a partially enlarged view of the display device main body.

FIG. 19 is an exploded perspective view of a lid member and a holding member constituting the display device.

FIG. 20 is a partially enlarged view of the display device main body.

### BEST MODE FOR CARRYING OUT THE INVENTION

Embodiments of the present invention will now be described with reference to the accompanying drawings in order to explain the present invention in more detail.

### First Embodiment

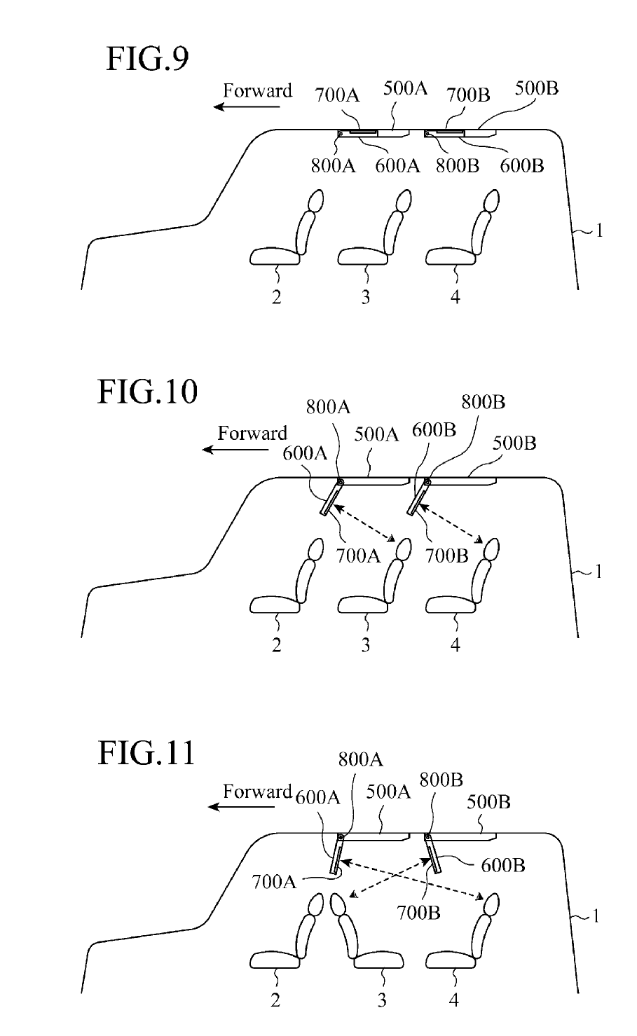

First, in order to clarify the present invention, a conventional display device holding structure in connection with the invention will be discussed. Within a motor vehicle 1 in FIG. 9, a forward-facing rear seat 3 and a forward-facing rear seat 4 are disposed behind a driver's seat 2 and behind the rear seat 3, respectively. A display device main body 500A is disposed slightly forward of the rear seat 3 on the ceiling of the vehicle interior. A display device 600A is housed in the display device main body 500A with the display device closed to the display device main body 500A in position 1 where an image surface 700A is faced upward.

A display device main body 500B having the same specification as that of the display device main body 500A is disposed slightly forward of the rear seat 4. A display device 600B is closed to the display device main body 500B to be housed therein in position 1 where an image surface 700B is faced upward.

A person sitting on the rear seat 3, as shown in FIG. 10, will confront the image surface 700A of the display device 600A and can view display information as shown by the dashed line arrow, by rotating the display device 600A housed in the display device main body 500A with a pivot 800A as a fulcrum that is located on the forward side of the vehicle 1 in the display device main body 500A, and that is disposed substantially horizontally and further in a direction orthogonal to the travelling direction, such that the free-end side of the display device is opened simply downwardly from position 1.

Similarly, a person sitting on the rear seat 4 also can confront the image surface 700B of the display device 600B to view display information as shown by the dashed line arrow, by rotating the display device 600B housed in the display device main body 500B with a pivot 800B as a fulcrum that is located on the forward side in the travelling direction of the vehicle 1 in the display device main body 500B and that is disposed substantially horizontally and further in a direction orthogonal to the travelling direction, such that the free-end side of the display device is opened directly downwardly from position 1.

Here, the rear seat 3 is a rotary seat changeable in orientation from the forward-facing orientation to the rearward-facing one, and as shown in FIG. 11, the person in the rear seat 3 can sit facing the person in the rear seat 4 by rotating the rear seat 3 so as to face rearward. In a condition where the persons can face each other with the rear seat 3 faced rearward, the person in the rear seat 4 can continue to confront and view the image surface 700A of the display device 600A as shown in FIG. 10. However, the person in the rear seat 3 rotated rearward confronts the backside of the image surface 700B and cannot view the image surface when the position shown in FIG. 10 is maintained; in order to enable such a view, the display device 600B has to be reversed.

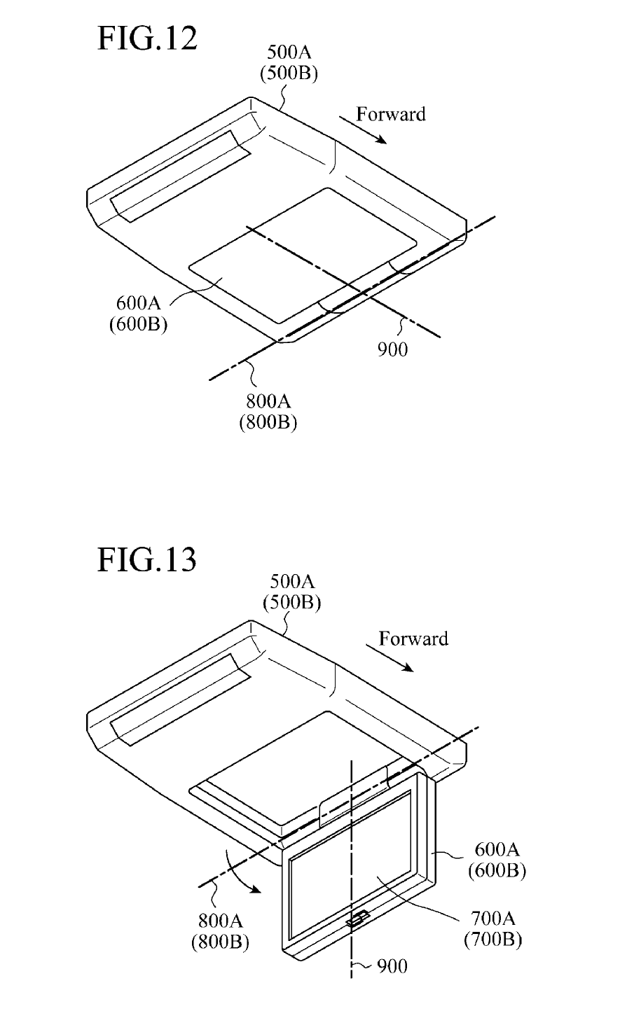

The display device main body 500B (500A) includes a mechanism for reversing the display device 600B (600A). As shown in FIG. 12-FIG. 16, the reversing mechanism is composed almost exclusively of another pivot 900 provided in a manner to be orthogonal to the pivot 800B, adjacent to thereto. It becomes possible for the person in the rear seat 3 to confront and view the image surface 700B as shown in FIG. 11 by rotating the display device 600B with the reversing mechanism.

When the display devices are housed in the respective display device main bodies after completion of the view, the display device 600A is housed in the display device main body 500A in position 1 where the image surface 700A is faced upward, due to an operation which pushes up the other-end side (the rear free-end side) of the display device 600A from the working state shown in FIG. 11 as it stands and also a closing operation which rotates the device with the pivot 800A as the fulcrum. The series of operations are shown by the flow of the operations that starts from the closed state shown in FIG. 12, and returns to the closed state shown in FIG. 12 through the view use in the opened state in FIG. 13.

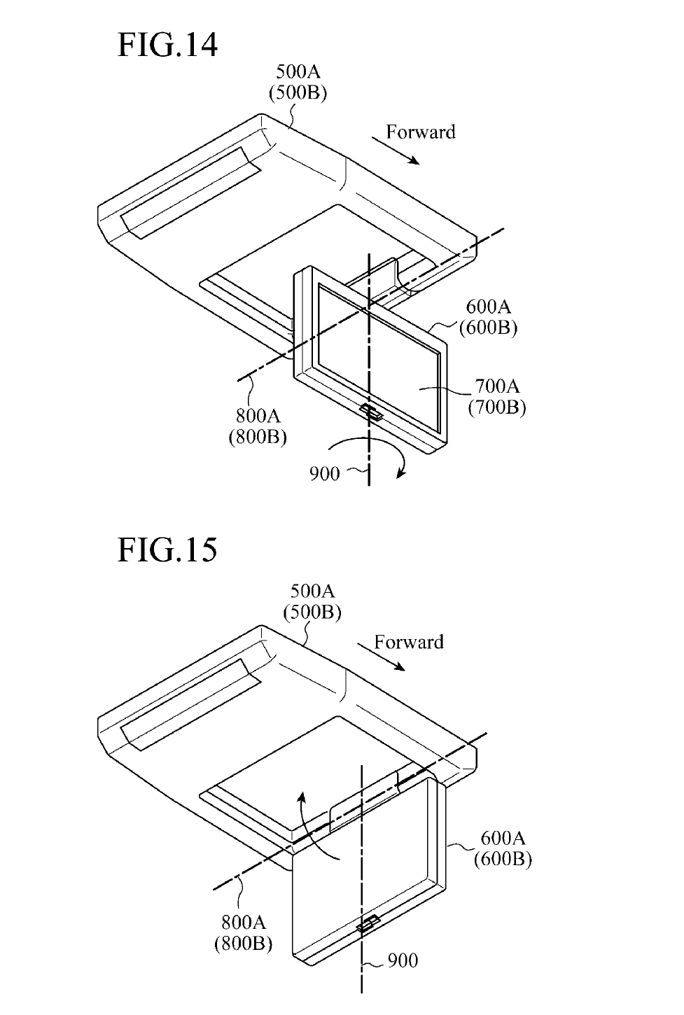

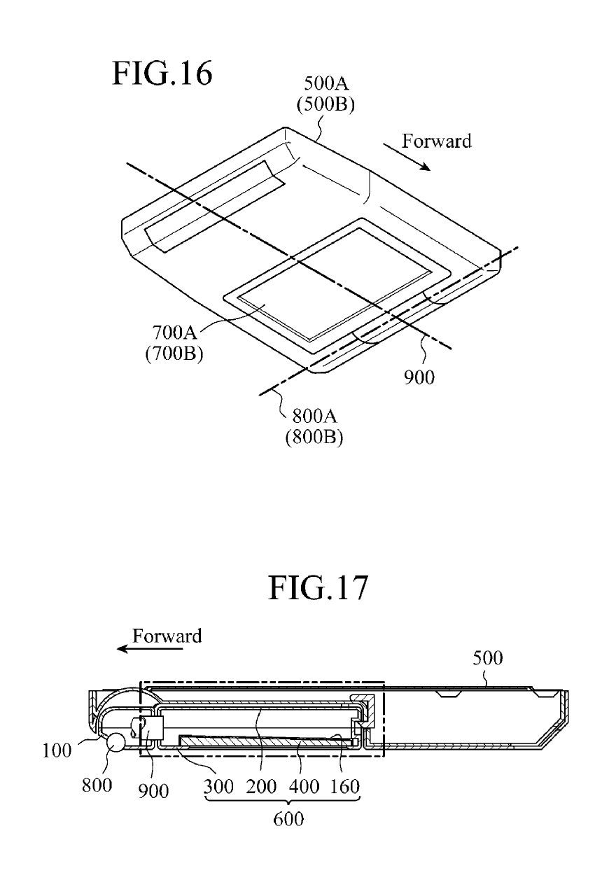

By contrast, the reversing operations are added thereto with respect to the operations of the display device 600B, as discussed above. Thus, if the operation that pushes up the other-end side (the rear free-end side) of the display device 600B from the state in service shown in FIG. 11 as it stands, and also the closing operation that rotates the display device with the pivot 800B as the fulcrum are carried out, the display device will be housed in the display device main body 500B in position 2 where the image surface 700B is faced downward. This operation process can be represented as the following procedure: an opening operation is performed from the closed state in FIG. 12 to arrive at an opened state in FIG. 13; and further a rotating (reversing) operation in FIG. 14 is performed to arrive at a housed state in FIG. 16 by way of a view use in a reversed state shown in FIG. 15.

In the case where a user of the display device 600B uses the display device in the reversed state (see FIG. 15) as shown in an example of FIG. 11, when the display device is housed in the display device main body 500B, the user does not take the trouble to return the position of the display device such that the device is housed in position 1, and the user usually pushes up the other-end side of the display device staying in the used condition to be housed in the display device main body, to thus be housed in position 2. When the display device is used in the reversed state, the display device is often housed in position 2; thus, two manners of position 1 and position 2 can be present mixedly in the housing ones of the display device.

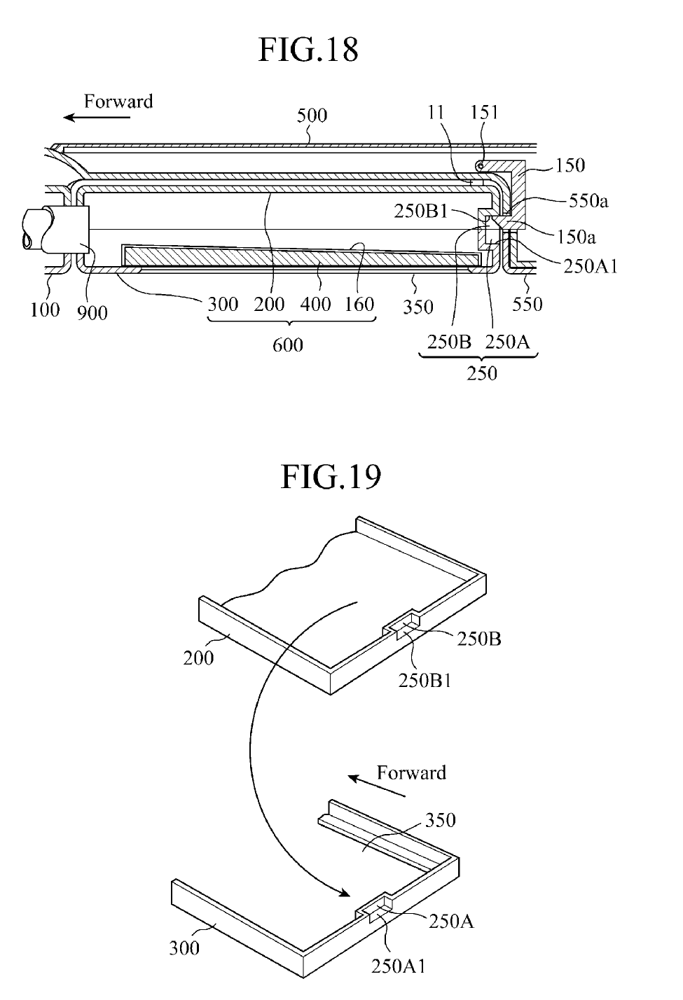

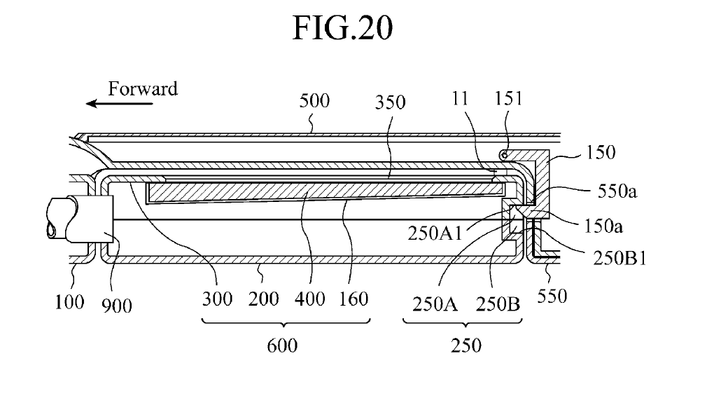

When there is no need of a view for the display device 600A (600B), the device is housed in the display device main body 500A (500B) in the closed state to be locked and held. It should be noted that the display device main bodies 500A, 500B have the same configuration with each other, and that the display devices 600A, 600B serving as constituent members therefore are also in the same relation. Thus, the display device main body and the display device will be hereinafter discussed by removing the subscripts A and B of the reference numerals to avoid the complexity. FIG. 17 shows the state where the display device 600 is locked and held in the closed state in the manner of position 2, and in FIG. 17, the display device and the peripheral members are surrounded with the frame of the dashed-two dotted line. FIG. 18 and FIG. 20 show in an enlarged dimension the portions surrounded by the frame.

In FIG. 17, FIG. 18, and FIG. 19, a holding member 300 has a shallow and rectangular shape, can house a display unit 400, and an opening 350 for exposing an image surface is formed at the bottom thereof. A chassis 160 serving as a holder to which the display unit 400 is attached is fixed at the holding member 300. A lid member 200 also has the substantially same shape as the holding member 300, and constitutes the display device 600 together with the holding member 300 housing and holding the display unit 400 by being placed in a superposed relation with the holding member such that the mating faces thereof on the opened side mate with each other, to unite with the holding member. In FIG. 19, the lid member 200 is superposed on the holding member 300 in a reversed way (as shown by an arrow from an aspect shown in the figure), and both the members are held in a united state by a suitable fixing holding means. The display device 600 thus constructed is pivoted to a connection member 100 by a pivot 900 on one-end side thereof (on the side of a forward direction). The connection member 100 is pivoted to the display device main body 500 by a pivot 800.

The pivot 800 has its axis substantially in a horizontal plane and is orthogonal to the forward direction. The pivot 900 is placed in a relation where its axis is orthogonal to the axis of the pivot 800. These pivot 800, connection member 100, and pivot 900 are shown as one example of support means for supporting the display device 600 openably and closably to the display device main body 500 on the one-end side thereof and further reversibly (rotatably) supporting the whole display device 600.

A lock concavity 250 for locking the display device to the display device main body 500 is provided on the other-end side of the display device 600. The lock concavity 250 is composed of a holding member side lock concavity 250A provided at the mating face on the other-end side of the holding member 300 and a lid member side lock concavity 250B provided at the mating face on the other-end side of the lid member 200.

The lock concavity 250 allows a lock member 150 to move in and out therefrom. The lock member 150 is pivoted on the base-end side thereof to the display device main body 500 by a shaft 151, and is urged in the direction where a tip pawl 150a thereof enters the lock concavity 250 by a torsion spring (not shown) working as an urging means.

The rotation of the lock member 150 brought about by the urging force is arranged to be restricted by a stopper (not shown) provided such that the tip pawl 150a stops at the position to which the tip pawl enters the lock concavity 250.

FIG. 17 and FIG. 18 show the case of position 2 where the display device is housed with the image surface faced downward. The tip pawl 150a goes in the lid member side lock concavity 250B through an opening formed in a vertical wall section of a display device housing panel 550 formed on the side of the display device main body 500 to abut against an inner wall 250B1, thus preventing the other-end section of the display device 600 from being lowered by the self-weight of the display device to hold the display device 600 in the closed condition. Here, in order to prevent the display device 600 from being rattled by vibrations, an elastic member 11 is attached on the other-end side of the display device 600 on the horizontal plane of the display device housing panel 550.

The process where the display device 600 is locked by the lock member 150 is as follows: when the other-end side of the display device 600 is lifted with the pivot 800 as a fulcrum, an inclined face formed at the back of the tip pawl 150a contacts and continues riding on the other-end section of the display device 600 by the force of the urging means, and when the inclined face arrives at the lock concavity 250, the tip pawl 150a goes in the lock concavity 250. Under such a condition, the elastic member 11 exists in a compressed state where the elastic member is placed tightly between the display device 600 (lid member 200) and the horizontal plane section of the display device housing panel 550. Here, when the force of lifting the display device is released, the other-end side of the display device 600 is lowered by the elastic force of the elastic member 11 and the self-weight of the display device 600, and the tip pawl 150a tightly contacts the inner wall 250B1 of the lid member side lock concavity 250B to cause the display device to enter a locked state. Even if the other-end side of the display device 600 is swung by external vibrations, it is intended that the interference function of the elastic member 11 prevents the display device from being rattled.

When releasing the locking engagement by the lock member 150, a force against the urging force of the torsion spring (not shown) is applied to the lock member 150 to rotate the lock member, and the tip pawl 150a is thereby detached from the lock concavity 250.

As discussed above, the housing manners of the display device 600 can be mixed by two manners of position 1 and position 2. FIG. 20 shows the case of position 1 in the housing manner where the display device 600 is housed with the image surface disposed upward. The tip pawl 150a goes in the holding member side lock concavity 250A through an opening 550a formed in a vertical wall section of the display device housing panel 550 formed on the side of the display device main body 500 to abut against an inner wall 250A1, thus preventing the other-end section of the display device 600 from being lowered by its self-weight to hold the display device 600 in the closed condition. It is intended that placing the elastic member 11 in a compression state exhibits the vibration prevention function thereof.

As seen from the above, the lock member 150 abuts against the inner wall 250B1 in position 2, and abuts against the inner wall 250A1 in position 1. The inner wall 250B1 is formed on the lid member 200, the inner wall 250A1 is formed on the holding member 300, and the lid member 200 and the holding member 300 are two members independent from each other, although they are fitted together and unitized. Thus, variations can arise easily in the condition where the two members are fitted with each other. The variations can make a difference between the degree of abutment of the lock member 150 against the inner wall 250A1 in position 1 and the degree of abutment of the lock member 150 against the inner wall 250B1 in position 2, which may also cause variations in the quake-proof performance; this is a problem.

Further, out of the members constituting the display device 600, when the weights between the lid member 200 and the holding member 300 are compared, there is a difference in weight between the both. For example, the holding member 300 holding the display unit 400 is heavier than the lid member 200. As shown in FIG. 17 and FIG. 18, in the manner where the lock member 150 locks the light lid member 200 in position 2, the heavy holding member 300 is held by the lid member 200, thus putting a heavy load on the fixing holding means that holds the lid member 200 and the holding member 300 in a unitized state.

Hereinafter, an embodiment of a display device holding structure according to the present invention will be described. The present invention involves an improvement in the display device holding structure discussed by referring to FIG. 9 to FIG. 20. In the following explanation, out of the constituent parts constituting the display device holding structure discussed in FIG. 9 to FIG. 20, the common constituent parts are designated by reference numerals similar to those shown in FIG. 9 to FIG. 20, and these explanations will be omitted.

In the past, the holding member 300 and the lid member 200 each have provided thereon a lock concavity to be locked by the lock member 150. More specifically, the holding member 300 is provided with the holding member side lock concavity 250A, the lid member 200 is provided with the lid member side lock concavity 250B, respectively, and those holding member side lock concavity 250A and lid member side lock concavity 250B are placed in a superposed relation to each other and unitized to constitute the lock concavity 250.

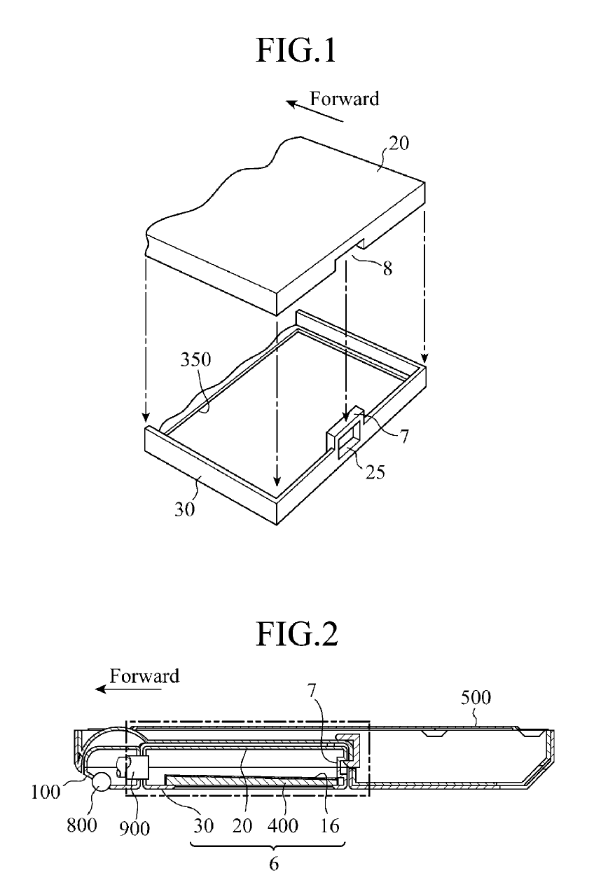

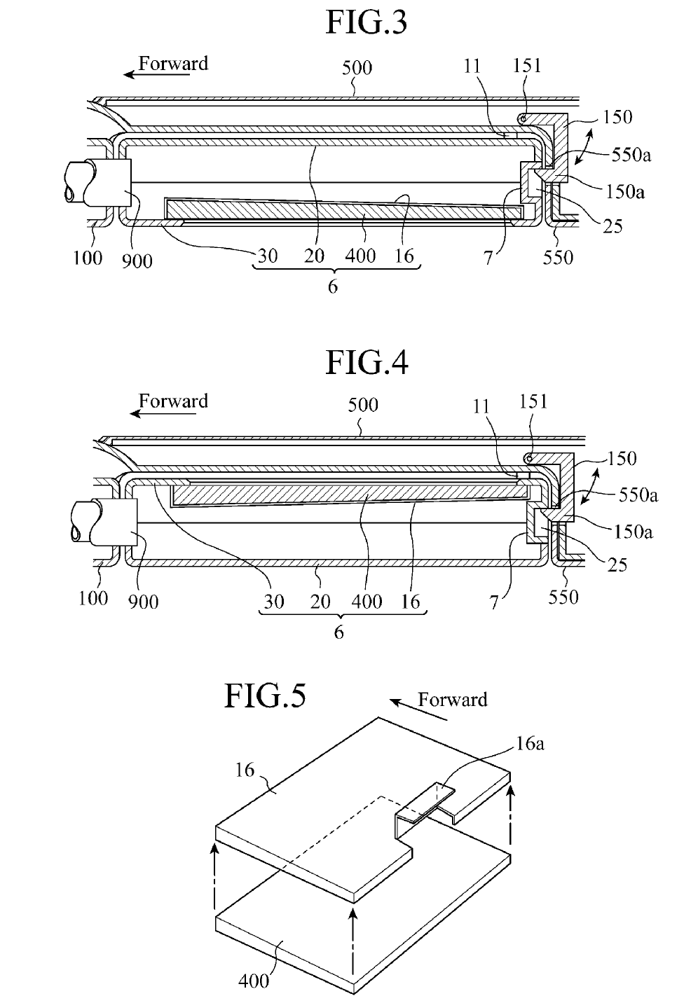

In contrast, in the embodiment, as shown in FIG. 1 to FIG. 4, only a holding member 30 corresponding to the conventional holding member 300 is provided with a lock concavity 25, while a lid member 20 corresponding to the conventional lid member 200 is provided without any lock concavity. In FIG. 2, the display device and the peripheral members are surrounded with the frame of the dashed-two dotted line, and FIG. 3 and FIG. 4 show in an enlarged dimension the surrounded portions thereof.

In such a way, when the lock concavity 25 is provided on either of the lid member 20 and the holding member 30, only on the holding member 30 in this example, even if the fitting condition thereof varies because of variations in the accuracy of the two members, the lid member 20 and the holding member 30, the lock concavity 25 is locked by the lock member 150 without suffering an effect of the variations. Further, the degree of abutment of the lock member 150 against the lock concavity 25 in position 1 and position 2 does not suffer the effect of the variations, which has no adverse effect on the vibration absorbing performance from the elastic member 11; thus, there is an advantage such that variations in quake-proof performance can be reduced.

Furthermore, when a heavier member, namely the holding member 30 in the embodiment is provided with the lock concavity 25 by way of example, in any of the case where the housing manner of the display device 6 composed of a lid member 20, a holding member 30, and a display unit 400 is position 2 where the display device is housed therein with the image surface disposed downward (see FIG. 3) and the case where the housing manner of the display device 6 is position 1 where the display device is housed with the surface disposed upward (see FIG. 4), the lock member 150 will lock the member, which is a heavier one, to hold the member. Particularly, in position 2 where the holding member 30, which is heavier, is placed below the lid member 20 (see FIG. 3), the display device holding structure takes a manner where the lid member 20 is placed on the holding member 30, and thus a heavy load is not imposed on the fixing holding means holding the holding member 30 and the lid member 20 in a unitized state. Thus, the lid member 20 and the holding member 30 are stabilized under the condition where both the members are held in a unitized state.

It should be appreciated that, when the display device 6 is housed in position 1 where the image surface is disposed upward (see FIG. 4), the display device holding structure is placed in the position where the lid member 20 is disposed downward and the lid member 20 is supported by the holding member 30 through the fixing holding means; however, the lid member 20 disposed downward is light in weight, and thus the fixing holding means does not have a heavy load imposed thereon.

### Second Embodiment

As shown in FIG. 1, in a lock concavity 25, from the side of a holding member 30 that is one member of either of the holding member 30 and a lid member 20 toward the side of the lid member 20 that is the other member, a convex section 7 that projects in a convex shape from a mating face of these two members is formed, while a concave section 8 to be fitted with the convex section 7 is formed in the lid member 20. Thus, the holding member 30 that is one member of a pair of members that are united has provided thereon the convex section 7 having the lock concavity 25, such that the convex section projects from the mating face thereof, while the lid member 20 that is the other member thereof has provided thereon the concave section 8 to be fitted with the convex section 7 in a shape buried from the mating face thereof, thus causing the one member to be supported by the lock member 150 in any of position 1 and position 2. Moreover, the convex section 7 and the concave section 8 have a fitting relationship with each other. Thus, when the two members are united, the ability of the two members to be assembled to each other is increased by the guide function of a fit section, and also the mating section is prevented from being dislocated.

### Third Embodiment

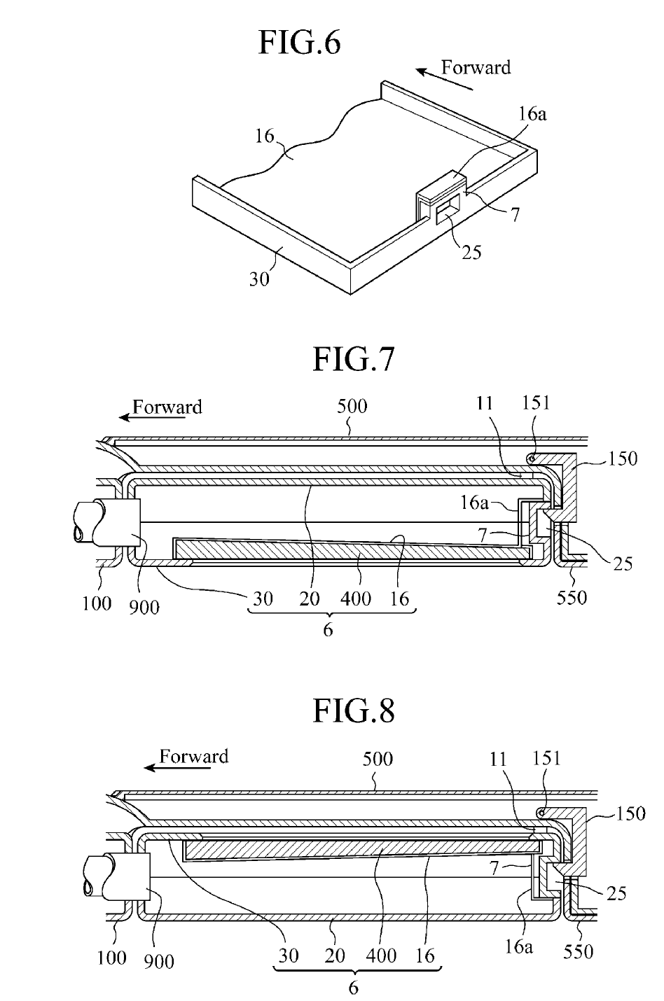

As shown in FIG. 5 to FIG. 8, a holding member 30 has fixed thereon a chassis 16 functioning as a holder to which a display unit 400 is attached. The marginal edge of the chassis 16 is partially cut and the portion of the edge is turned out to form a turned-out lug in an L-shape, and the turned-out lug 16a is located at the back of the convex section 7 as an auxiliary functional member, thus enabling the convex section 7 to be reinforced and protected.

### INDUSTRIAL APPLICABILITY

As discussed above, the display device holding structure according to the present invention is a display device holding structure arranged in a display device main body, in order to improve the earthquake resistance, and enable a display device to be stably held, and includes a holding member for housing and holding a display unit; a lid member that is superposed on the holding member to be united to thus form a display device; a support means that is provided between one-end side of the display device and the main body and supports the display device openably and closably, and reversibly with respect to the main body; a lock concavity provided on the other-end side of the display device, for locking the other-end side to the main body; and a lock member provided in the main body to be engageable and disengegeable with the lock concavity. The display device holding structure is further arranged such that the lock concavity is provided in either of the holding member and the lid member. Thus, the display device holding structure is suitable for use in a display device holding structure for allowing a display panel such as a display disposed on a ceiling of an automobile, e.g., to be adjusted to a position where a viewer can easily see the display, and thereafter allowing the display panel to be locked and held at a housed state where the display panel is closed alongside the ceiling.

1. A display device holding structure arranged within a display device main body, comprising:
a holding member for housing and holding a display unit;
a lid member that is superposed on the holding member to be united to thus form a display device;
a support means that is provided between one-end side of the display device and the main body and supports the display device openably and closably, and reversibly with respect to the main body;
a lock concavity, provided on the other-end side of the display device, for locking the other-end side to the main body; and
a lock member provided in the main body to be engageable with the lock concavity,
wherein the lock concavity is provided in either of the holding member and the lid member.

2. The display device holding structure according to claim 1, wherein the lock concavity is formed in a convex section projecting in a convex shape from the mating face of either of the holding member and the lid member, with the mating face mating with the mating face of the other member, and a concave section that is fitted over the convex section is formed in the other member.

3. The display device holding structure according to claim 2, wherein the holding member has fixed thereon a chassis to which the display unit is secured, the marginal edge of the chassis is partially cut and the portion of the edge is turned out to form a turned-out lug, and the turned-out lug is located at the back of the convex section.
